(19) United States
(12) Patent Application Publication
(10) Pub. No.: US 2024/0186272 A1
(43) Pub. Date: Jun. 6, 2024

(54) POWER MODULE

(71) Applicants: Hyundai Motor Company, Seoul (KR); Kia Corporation, Seoul (KR)

(72) Inventors: Myung III YOU, Seo-Gu (KR); Jun Hee PARK, Hwaseong-Si (KR)

(73) Assignees: Hyundai Motor Company, Seoul (KR); Kia Corporation, Seoul (KR)

(21) Appl. No.: 18/218,756

(22) Filed: Jul. 6, 2023

(30) Foreign Application Priority Data
Dec. 5, 2022 (KR) 10-2022-0167892

(51) Int. Cl. H01L 23/66; H01L 23/00; H01L 23/495; H05K 1/18

(52) U.S. Cl. CPC H01L 23/66; H01L 23/49541; H01L 24/48; H05K 1/189; H01L 2224/48137; H01L 2224/48175; H05K 2201/095

(57) ABSTRACT

A power module is provided. In the power module, electrical connection to the outside is enabled through a FPCB made to be flexible and deformable, and as terminals for signal transmission and wire bonding for connecting terminals are eliminated, insulation is ensured and the overall size is reduced.

### CROSS REFERENCE TO RELATED APPLICATION

The present application claims priority to Korean Patent Application No. 10-2022-0167892, filed Dec. 5, 2022, the entire contents of which is incorporated herein for all purposes by this reference.

### BACKGROUND OF THE PRESENT DISCLOSURE

### Field of the Present Disclosure

The present disclosure relates to a power module configured for performing an electrical connection without terminals for signal transmission and wire bonding for connecting terminals.

### Description of Related Art

A power converter (e.g., an inverter), which is one of core components of a hybrid vehicle and an electric vehicle, is the main component of an eco-friendly vehicle, and many technical developments of the power converter are underway. Developing a power module, which is a core component of the power converter and costs the most, is a key technology in the field of eco-friendly vehicles.

In a power module, because heat dissipation of a chip is dissipated only on one side when a single-sided cooling method is applied to the power module, the heat dissipation to upper and lower portions of the chip is enabled by applying a double-sided cooling method.

However, in a case of the conventional double-sided cooling method, in terms of structure, performance improvement of thermal resistance may be achieved by use of a high heat dissipation material, resulting in an increase in cost.

Accordingly, when a flip chip is applied for the performance improvement of heat dissipation, not only insulation problems occur at the upper and lower portions of a chip, but also wire bonding is required to connect the chip and signal leads.

For the present reason, in the case of a power module in which the chip is mounted, loss of heat dissipation areas of a substrate occurs due to wire bonding patterns, the size of the substrate is increased, and cost is increased.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module in which an electrical connection to the outside is enabled through a FPCB made to be flexible and deformable, so that wire bonding is eliminated, whereby insulation is ensured and the overall size is reduced.

According to an exemplary embodiment of the present disclosure for achieving the above objective, there is provided a power module including: a substrate; chips connected to the substrate; and a Flexible Printed Circuit Board (FPCB) provided between the substrate and the chips, be provided with a plurality of circuit lines forming patterns for electrical connection of each chip, and extending to enable electrical connection to an outside.

The FPCB may include the plurality of chips, and the circuit lines may form the patterns for the electrical connection of each chip.

In a state of being provided between the substrate and the chips, the FPCB may have through holes formed at respective portions of the FPCB, which match the chips.

In the FPCB, the through holes may be formed smaller than the respective chips, so that portions to which the chips and the circuit lines are connected may be covered and insulated.

The FPCB may be provided with the circuit lines embedded in the FPCB and insulated.

A connector may be provided at a terminal of the FPCB, and the respective circuit lines electrically connected to the chips may be connected to the connector.

Meanwhile, according to an exemplary embodiment of the present disclosure for achieving the above objective, there is provided a power module including: an upper substrate and a lower substrate; chips connected to the upper substrate or the lower substrate; spacers provided to be connected to the upper substrate and the lower substrate and on which the respective chips are disposed; and a FPCB provided between the chips and the upper substrate or the lower substrate, be provided with a plurality of circuit lines forming patterns for electrical connection of each chip, and extending to enable electrical connection to an outside.

The chips and the FPCB may be provided between the upper substrate and the spacers, the upper substrate may be disposed to be connected to an upper side of the FPCB, and the chips may be disposed to be connected to a lower side of the FPCB.

In a state of being provided between the upper substrate and the chips, the FPCB may have through holes formed at respective portions of the FPCB, which match the chips.

A connector may be provided at a terminal of the FPCB, and the respective circuit lines electrically connected to the chips may be connected to the connector.

In the power module having the structure as described above, electrical connection to the outside is enabled through the FPCB made to be flexible and deformable, and as the terminals for signal transmission and the wire bonding for connecting terminals are eliminated, insulation is ensured and the overall size is reduced.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a view exemplarily illustrating a power module according to an exemplary embodiment of the present disclosure.

FIG. 2 is a view exemplarily illustrating circuit lines of a FPCB and a chip of the power module shown in FIG. 1.

FIG. 3 is a view exemplarily illustrating a connector of the FPCB according to the power module shown in FIG. 1.

FIG. 4 is a cross-sectional side view of the power module according to an exemplary embodiment of the present disclosure.

FIG. 5 is a view exemplarily illustrating a flip chip structure according to a conventional power module.

FIG. 6 is a cross-sectional side view of the conventional power module shown in FIG. 5.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, an exemplary embodiment included in the present specification will be described in detail with reference to the accompanying drawings, but regardless of the reference numerals, the same or similar components are provided identical reference numbers, and the overlapping description thereof will be omitted.

The suffixes “module” and “part/unit” for the components used in the following descriptions are provided or mixed in consideration of only the ease of writing the specification, and the suffixes do not have distinct meanings or roles by themselves.

In describing the exemplary embodiment included in the present specification, when it is determined that a detailed description of a related known technology may obscure the subject matter of the exemplary embodiment included in the present specification, the detailed description thereof will be omitted. Furthermore, the accompanying drawings are only for easy understanding of the exemplary embodiment included in the present specification, the technical idea included in the present specification is not limited by the accompanying drawings, and it should be understood that the accompanying drawings include all changes, equivalents, or substitutes, which are included in the spirit and technical scope of the present disclosure.

It will be understood that, although the terms including ordinal numbers, such as first, second, etc. may be used herein to describe various elements, these elements should not be limited by these terms. These terms are only used for distinguishing one component from another component.

When a component is described as being “connected”, “coupled”, or “linked” to another component, that component may be directly connected, coupled, or linked to that other component. However, it should be understood that yet another component between each of the components may be present. In contrast, it should be understood that when a component is referred to as being “directly coupled” or “directly connected” to another component, there are no intervening components present.

As used herein, the singular forms are intended to include the plural forms as well, unless the context clearly indicates otherwise.

It will be further understood that the terms “comprise”, “include”, “have”, etc. when used in the present specification, specify the presence of stated features, integers, steps, operations, elements, components, and/or combinations thereof but do not preclude the presence or addition of one or more other features, integers, steps, operations, elements, components, and/or combinations thereof.

The controller may include: a communication device configured for communicating with other controllers or sensors to control functions in charge; a memory for storing an operating system, logic instructions, and input/output information; and one or more processors for performing determinations, determinations, and decisions, which are required for controlling the functions in charge.

Hereinafter, a power module according to an exemplary embodiment of the present disclosure will be described with reference to the accompanying drawings.

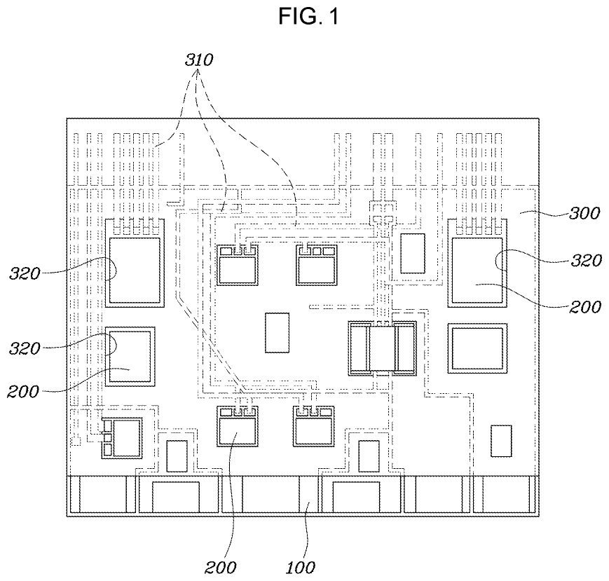

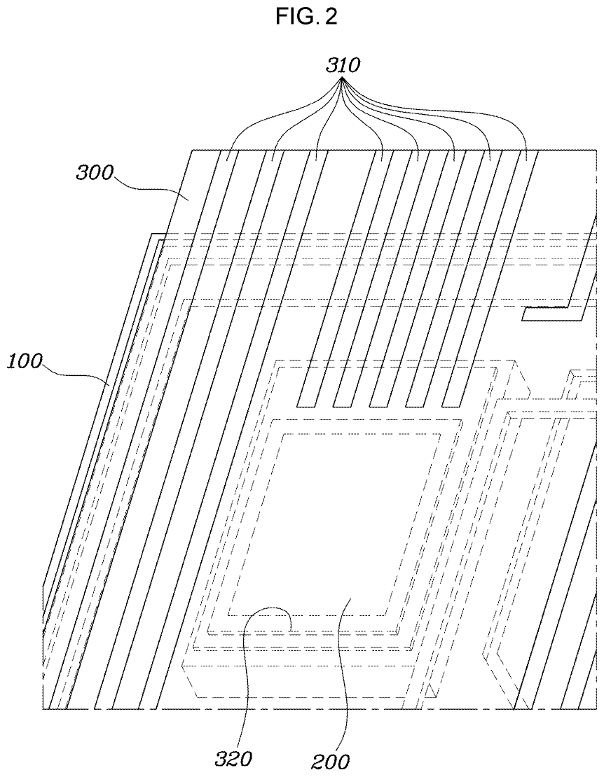

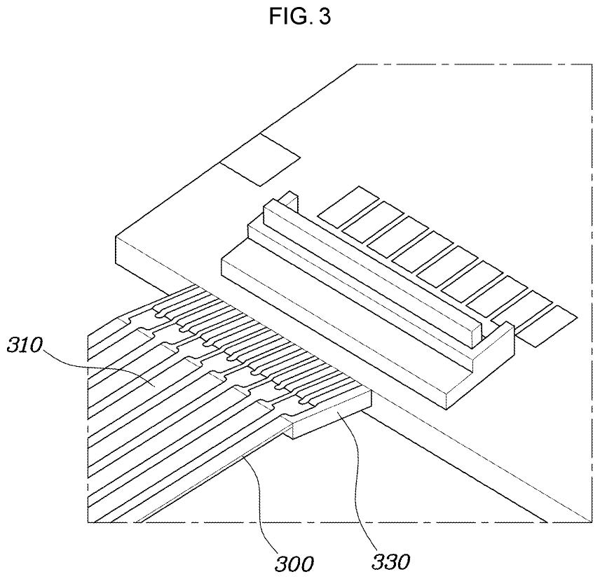

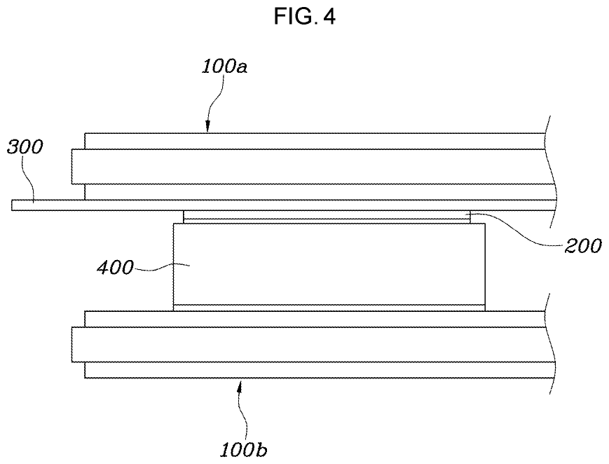

FIG. 1 is a view exemplarily illustrating a power module according to the exemplary embodiment of the present disclosure. FIG. 2 is a view exemplarily illustrating circuit lines of a FPCB and a chip of the power module shown in FIG. 1. FIG. 3 is a view exemplarily illustrating a connector of the FPCB according to the power module shown in FIG. 1. FIG. 4 is a cross-sectional side view of the power module according to an exemplary embodiment of the present disclosure.

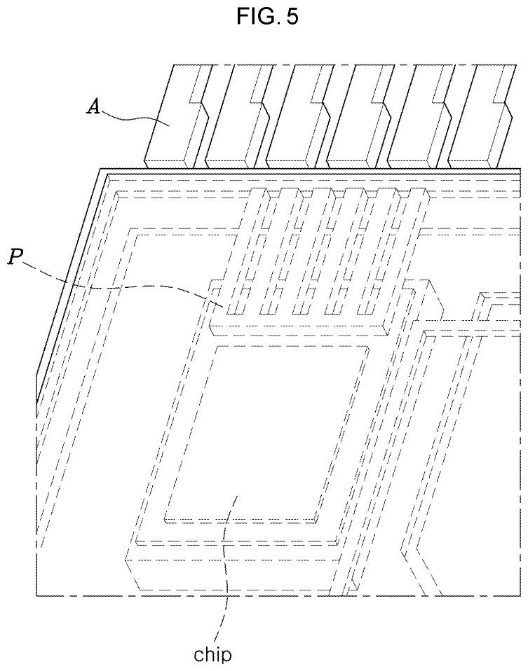

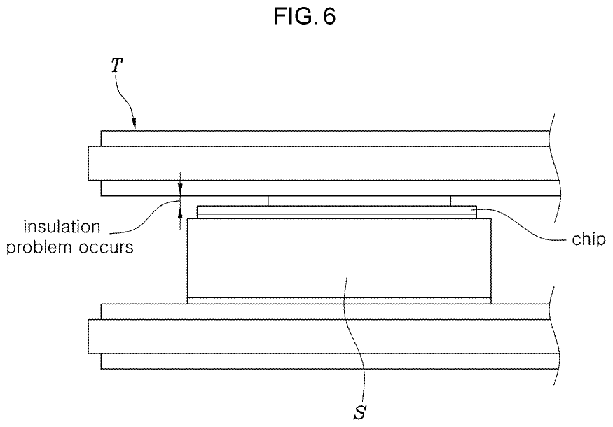

FIG. 5 is a view exemplarily illustrating a flip chip structure according to a conventional power module. FIG. 6 is a cross-sectional side view of the conventional power module shown in FIG. 5.

As shown in FIG. 1, FIG. 2, and FIG. 3, the power module according to an exemplary embodiment of the present disclosure includes: a substrate 100; chips 200 connected to the substrate 100; and a Flexible Printed Circuit Board (FPCB) 300 provided between the substrate 100 and the chips 200, being provided with a plurality of circuit lines 310 forming the patterns for the electrical connection of each chip 200, and extending to enable an electrical connection to the outside.

Accordingly, the substrate 100, chips 200, and FPCB 300 may be configured to be molded, in a state of being connected to each other, to allow respective insides thereof to be insulated.

In the power module according to the exemplary embodiment of the present disclosure, signal leads for signal transmission are eliminated, and as the signal leads are eliminated, the patterns provided on the substrate and the wire bonding for electrically connecting the chips and the signal leads are eliminated.

As described above, in an exemplary embodiment of the present disclosure, a heat dissipation area of the substrate 100 may be additionally secured by eliminating the wire bonding and patterns, and as the signal leads are eliminated, insulation distances are easily secured and the overall size is reduced.

To the present end, the exemplary embodiment of the present disclosure is configured with the substrate 100 and the chips 200. The FPCB 300 is provided between the substrate 100 and the chips 200, and the FPCB 300 is provided with a plurality of circuit lines 310 forming the patterns for the electrical connection of each chip 200, whereby the chips 200 are electrically connected via the FPCB 300.

That is, the FPCB 300 is formed to extend to allow the plurality of chips 200 to have electrical connections and to additionally enable an electrical connection to the outside thereof, whereby each chip 200 is able to transmit power and signal through the FPCB 300, and may be electrically connected to the outside through the FPCB 300 without components such as separate signal leads.

As described above, in an exemplary embodiment of the present disclosure, because the FPCB 300 is configured as the signal leads and the patterns formed on the substrate 100, there is no heat dissipation loss due to forming the patterns on the substrate 100, additional processes, such as performing wire bonding for signal lead connection, are eliminated, and the patterns for the signal lead connection are also eliminated, whereby heat dissipation areas may be secured.

Describing the above-described present disclosure in detail, the FPCB 300 includes the plurality of chips 200, and the circuit lines 310 form patterns for electrical connection of each chip 200.

The FPCB 300 may include all of the plurality of chips 200 connected to the substrate 100. Accordingly, the FPCB 300 may have a larger area than that of the substrate 100 and to cover the substrate 100, and when it is possible that an electrical connection of each chip 200 is enabled by including all the plurality of chips 200, the forms of the FPCB 300 may be diversified.

Furthermore, the FPCB 300 is provided with the circuit lines 310, and in the instant case, the circuit lines 310 is formed to be electrically connected to each chip 200 in a state where the FPCB 300 is disposed on the substrate 100. Such circuit lines 310 form specific patterns, to be connected to each chip 200, allowing each chip 200 to be electrically connected thereto.

Furthermore, in a state of being provided between the substrate 100 and the chips 200, the FPCB 300 has through holes 320 formed at respective portions that match chips 200.

In the present way, the through holes 320 are formed in the FPCB 300, and thus the chips 200 may be exposed through the respective through holes 320. For the present reason, even when the FPCB 300 is provided between the substrate 100 and the chips 200, the chips 200 may be in contact with the substrate 100 through the respective through holes 320, smoothly dissipating heat.

Furthermore, in the FPCB 300, because the through holes 320 are formed smaller than the respective chips 200, portions to which the chips 200 and the circuit lines 310 are connected may be covered and insulated.

For the present reason, the chips 200 are exposed through the respective through holes 320, and may be electrically connected to the circuit lines 310 of the FPCB 300. That is, in a state where the through holes 320 of the FPCB 300 are matched to respective chips 200, some of the FPCB 300 are formed to cover the portions to which the chips 200 and the circuit lines 310 are connected, so that the chips 200 and the circuit lines 310 may be electrically connected in the FPCB 300, and the portions to which the chips 200 and the circuit lines 310 are connected may be insulated, preventing electrical burnout.

The number of through holes 320 of the FPCB 300 may be configured to be the same as the number of chips 200 connected to the substrate 100, and the through holes 320 may be formed in the same shapes as the external shapes of the respective chips 200.

Meanwhile, the FPCB 300 may be provided so that the circuit lines 310 are embedded therein and insulated. In the present way, in the FPCB 300, patterns forming the circuit lines 310 are embedded so as not to be exposed to the outside thereof, and thus are insulated.

Furthermore, the FPCB 300 may be configured to be flexible and deformable. That is, the FPCB 300 is formed to be deformable by bending, thereby being able to configure the circuit lines 310 as a three-dimensional wiring. Furthermore, the FPCB 300 is extended for electrical connection to the outside and configured to be flexible and deformable, and thus the degree of freedom of electrical connection positions is ensured.

A connector 330 is provided at a terminal of the FPCB 300, and respective circuit lines 310 electrically connected to the chips 200 may be connected to the connector 330.

As shown in FIG. 3, the connector 330 for electrical connection may be provided at the terminal of the FPCB 300. That is, since the circuit lines 310 are provided in the FPCB 300 for electrical connections of the chips 200 and the connector 330 is provided at the terminal of the FPCB 300, the FPCB 300 may be electrically connected to a control board and a gate board, which are electrical components, via the connector 330.

Furthermore, the conventional power module performs electrical connection by use of signal leads, and an assembly process such as soldering is required for connection of the signal leads. In the present manner, it is difficult to accurately match positions of the signal leads, and defects may occur due to assembly tolerances during the soldering process.

In contrast, in an exemplary embodiment of the present disclosure, electrical connection is performed through the connector 330 provided in the FPCB 300, so that the electrical connection is enabled with a fitting structure, defects due to assembly tolerances are prevented, and the degree of design freedom is ensured.

In the power module having the structure as described above, electrical connection to the outside is enabled through the FPCB 300 made to be flexible and deformable, and as the terminals for signal transmission and the wire bonding for connecting terminals are eliminated, insulation is ensured and the overall size is reduced.

Meanwhile, as shown in FIG. 4, the exemplary embodiment of the present disclosure includes: an upper substrate 100a and a lower substrate 100b; chips 200 connected to the upper substrate 100a or the lower substrate 100b; spacers 400 provided to connect the upper substrate 100a and the lower substrate 100b to each other and on which the respective chips 200 are disposed; and a Flexible Printed Circuit Board (FPCB) 300 provided between the chip 100 and the upper substrate 100a or lower substrate 100b, being provided with a plurality of circuit lines 310 forming the patterns for the electrical connection of each chip 200, and being extended to enable electrical connection to the outside.

Accordingly, the spacers 400 are provided between the upper substrate 100a and the lower substrate 100b, and the upper substrate 100a and the lower substrate 100b are physically and electrically connected to each other via the spacers 400.

The chips 200 connected to the respective spacers 400 are disposed between the upper substrate 100a and the lower substrate 100b, and heat generated from the chips 200 is transferred to the upper substrate 100a and the lower substrate 100b, whereby the chips 200 are cooled.

Here, the FPCB 300 is provided between the chips 200 and the upper substrate 100a or lower substrate 100b, and the FPCB 300 is provided with the plurality of circuit lines 310 forming the patterns for the electrical connection of each chip 200, whereby the chips 200 are electrically connected via the FPCB 300. In the exemplary embodiment of the present disclosure, each chip 200 is provided to be connected to the upper substrate 100a.

In a state of being provided between the substrate 100 and the chips 200, such a FPCB 300 may have through holes 320 formed at respective portions of the FPCB, which match the chips 200.

In the present way, the through holes 320 are formed in the FPCB 300, and thus the chips 200 may be exposed through the respective through holes 320. For the present reason, even when the FPCB 300 is provided between the substrate 100 and the chips 200, the chips 200 may be in contact with the substrate 100 through the respective through holes 320, smoothly dissipating heat.

Furthermore, the FPCB 300 may be configured to be flexible and deformable. That is, the FPCB 300 is formed to be deformable by bending, being able to configure the circuit lines 310 as a three-dimensional wiring. Furthermore, the FPCB 300 is extended for electrical connection to the outside and configured to be flexible and deformable, and thus the degree of freedom of electrical connection positions is ensured.

Furthermore, the connector 330 is provided at a terminal of the FPCB 300, and respective circuit lines 310 electrically connected to the chips 200 may be connected to the connector 330.

Accordingly, in an exemplary embodiment of the present disclosure, electrical connection is performed through the connector 330 provided in the FPCB 300, so that the electrical connection is enabled with a fitting structure, defects due to assembly tolerances are prevented, and the degree of design freedom is ensured.

In the present way, the FPCB 300 is formed to extend, to allow the plurality of chips 200 to have electrical connections and to additionally enable an electrical connection to the outside thereof, whereby each chip 200 is able to transmit power and signal through the FPCB 300, and may be electrically connected to the outside through the FPCB 300 without components such as separate signal leads.

As described above, in an exemplary embodiment of the present disclosure, because the FPCB 300 is configured as the signal leads and the patterns formed on the substrate 100, there is no heat dissipation loss due to forming the patterns on the substrate 100, additional processes, such as performing wire bonding for signal lead connection, are eliminated, and the patterns for the signal lead connection are also eliminated, whereby heat dissipation areas may be secured.

Here, the respective chips 200 and the FPCB 300 are provided between the upper substrate 100a and the spacer 400, and are arranged so that the upper substrate 100a is connected to an upper side of the FPCB 300 and the respective chip 200 are connected to a lower side of the FPCB 300.

For the present reason, heat of upper portions of the chips 200 may be directly dissipated through the upper substrate 100a, and heat of lower portions of the chips 200 may be dissipated through the respective spacers 400.

Through the present way, as shown in FIG. 5 and FIG. 6, generally, when the flip chip structure is used, heat dissipation loss occurs, as patterns P for connection of signal leads A should exist. Furthermore, when chips are provided between an upper substrate T and respective spacers S generally, separation spaces are generated, whereby an insulation problem occurs. Furthermore, because securing spaces between the upper substrate T and the spacers Sis difficult, there is also a limitation in connecting the signal leads A. Furthermore, as the spacers each including a larger area than that of the respective chips are disposed, the insulation function is degraded due to overflow of solder to the side thereof.

However, as may be seen in FIG. 4, in an exemplary embodiment of the present disclosure, the FPCB 300 is bonded between the upper substrate 100a and the chips 200 to perform stable heat dissipation, and as the FPCB 300 forms the externally extending form, electrical connection may be performed by simple assembly through the connector 330.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
a substrate;
chips connected to the substrate; and
a Flexible Printed Circuit Board (FPCB) provided between the substrate and the chips, being provided with a plurality of circuit lines forming patterns for electrical connection of each chip, and extending to enable electrical connection to an outside.

2. The power module of claim 1, wherein the FPCB includes the plurality of chips, and the circuit lines form the patterns for the electrical connection of each chip.

3. The power module of claim 1, wherein, in a state of being provided between the substrate and the chips, the FPCB includes through holes formed on the FPCB at respective portions of the FPCB, which match the chips.

4. The power module of claim 3, wherein, in the FPCB, each size of the through holes is formed smaller than the respective chips, so that portions to which the chips and the circuit lines are connected are covered and insulated.

5. The power module of claim 1, wherein the FPCB is provided with the circuit lines embedded in the FPCB and insulated.

6. The power module of claim 1, wherein a connector is provided at a terminal of the FPCB, and the respective circuit lines electrically connected to the chips are connected to the connector.

7. The power module of the claim 1,
wherein the substrate includes an upper substrate and a lower substrate,
wherein the chips are connected to the upper substrate or the lower substrate,
wherein spacers on which the respective chips are disposed are provided to be connected to the upper substrate and the lower substrate, and
wherein the FPCB is provided between the chips and the upper substrate or the lower substrate.

8. The power module of claim 7, wherein the chips and the FPCB are provided between the upper substrate and the spacers, the upper substrate is disposed to be connected to an upper side of the FPCB, and the chips are disposed to be connected to a lower side of the FPCB.

9. The power module of claim 7, wherein, in a state of being provided between the upper substrate and the chips, the FPCB includes through holes formed on the FPCB at respective portions of the FPCB, which match the chips.

10. The power module of claim 7, wherein a connector is provided at a terminal of the FPCB, and the respective circuit lines electrically connected to the chips are connected to the connector.

11. A power module comprising:
an upper substrate and a lower substrate;
chips connected to the upper substrate or the lower substrate;
spacers provided to be connected to the upper substrate and the lower substrate and on which the respective chips are disposed; and
a Flexible Printed Circuit Board (FPCB) provided between the chips and the upper substrate or the lower substrate, being provided with a plurality of circuit lines forming patterns for electrical connection of each chip, and extending to enable electrical connection to an outside.

12. The power module of claim 11, wherein the chips and the FPCB are provided between the upper substrate and the spacers, the upper substrate is disposed to be connected to an upper side of the FPCB, and the chips are disposed to be connected to a lower side of the FPCB.

13. The power module of claim 11, wherein, in a state of being provided between the upper substrate and the chips, the FPCB includes through holes formed on the FPCB at respective portions of the FPCB, which match the chips.

14. The power module of claim 11, wherein a connector is provided at a terminal of the FPCB, and the respective circuit lines electrically connected to the chips are connected to the connector.
